(19) United States
(12) Patent Application Publication
(10) Pub. No.: US 2026/0117592 A1
(43) Pub. Date: Apr. 30, 2026

(54) METHOD AND SYSTEM FOR CALCULATING CLEAM AZIMUTH IN PRESENCE OF MAGNETIC INTERFERENCE FROM OFFSET WELLS DURING DRILLING

(71) Applicant: Gunnar LLLP, Magnolia, TX (US)

(72) Inventor: Joe Burke, Spring, TX (US)

(21) Appl. No.: 19/371,350

(22) Filed: Oct. 28, 2025

Related U.S. Application Data
(60) Provisional application No. 63/713,282, filed on Oct. 29, 2024.

(51) Int. Cl. E21B 7/04; E21B 44/00; E21B 47/0228; G01R 33/02

(52) U.S. Cl. CPC E21B 7/04; E21B 44/00; E21B 47/0228; G01R 33/0206

(57) ABSTRACT

Methods and systems are disclosed for magnetic ranging while drilling. The system has a hardware component and a software component that allows for the collection and manipulation of magnetic signals to provide for a clean or corrected azimuth reading that can be used in directional drilling. The method involves collecting the magnetic field and accelerometer component data, smoothing the data if needed, identifying peaks and troughs in axial and radial components, determining pole segments by fitting to a monopole model and calculating a pseudo (interference free) cleaned azimuth reading by substituting the bz component taken at the solved pole position into the azimuth calculation at the axial peak and trough locations and taking the average of these two angles for the approximation of the cleaned azimuth at the pole position.

### FIELD OF THE INVENTION

The present disclosure relates to devices and methods involved with performing measurements from a subterranean wellbore or other such underground void to produce a relative distance and direction from one point in three-dimensional space to another. In particular, the present disclosure utilizes a novel method and system that derives a clean magnetic azimuth by taking advantage of the magnetic properties and magnetic signature of magnetic poles and analyzing selected axial and radial components of a magnetic field and using these in the clean azimuth calculation.

### BACKGROUND INFORMATION

In subterranean drilling operations, there is often a need to determine the relative location and distance from the drilling operation to surrounding wellbores. Subterranean drilling operations often encounter magnetic interference from other sources, particularly when drilling in proximity to existing wells located in a formation. This magnetic interference encountered during drilling can distort measured magnetic azimuth readings, which are critical for determining the wellbore's direction and are essential to avoid collisions (or to intentionally collide in some applications) with nearby wells and ensure safe and efficient drilling operations. Current methods to overcome this issue are to use gyros for azimuthal reference, as the magnetometer methods are no longer reliable. However, the use of gyros for azimuth determination are also not ideal due to added cost and measurement quality (specifically at higher inclinations). The need for a system and method to determine a reliable azimuth during directional drilling exists.

### SUMMARY

A system and method for obtaining a cleaned or “pseudo” magnetic azimuth while using magnetic ranging techniques is disclosed. A downhole drill bit is rotated in a well attached to a drill string that contains components that can be used to capture magnetic field component data (bx, by, bz), gravitation field component data (gx, gy, gz) and measured depth (md). Data obtained from these components is used in the method for determining the corrected pseudo azimuth when the well is in close proximity to the adjacent well.

The disclosed method provides a novel approach to calculate a cleaned or pseudo magnetic azimuth by effectively taking advantage of the magnetic properties and magnetic signature of magnetic poles along the adjacent wellbore to select a sampling of the data. This is achieved by analyzing the axial and radial components of the magnetic field and extracting the sensor components where the axial and radial fields from the interference source are at a minimum and using these in the azimuth calculation. The cleaned pseudo azimuth calculation is particularly beneficial when drilling close to other wells, where magnetic interference is more pronounced. The cleaned azimuth calculation can be further used in the magnetic ranging methods, and alleviates the necessity to run gyro.

### BRIEF DESCRIPTION OF THE DRAWINGS

FIG. 1 is an example of a drilling rig and wellbore configuration with which the disclosed method may be used.

FIG. 2 is an example of an MWD (Measurement While Drilling) Directional tool as shown in FIG. 1.

FIG. 2A is another example of a drilling rig and wellbore configuration which the disclosed method may be used.

FIG. 3 depicts a flow chart of one disclosed embodiment.

### DETAILED DESCRIPTION OF THE INVENTION

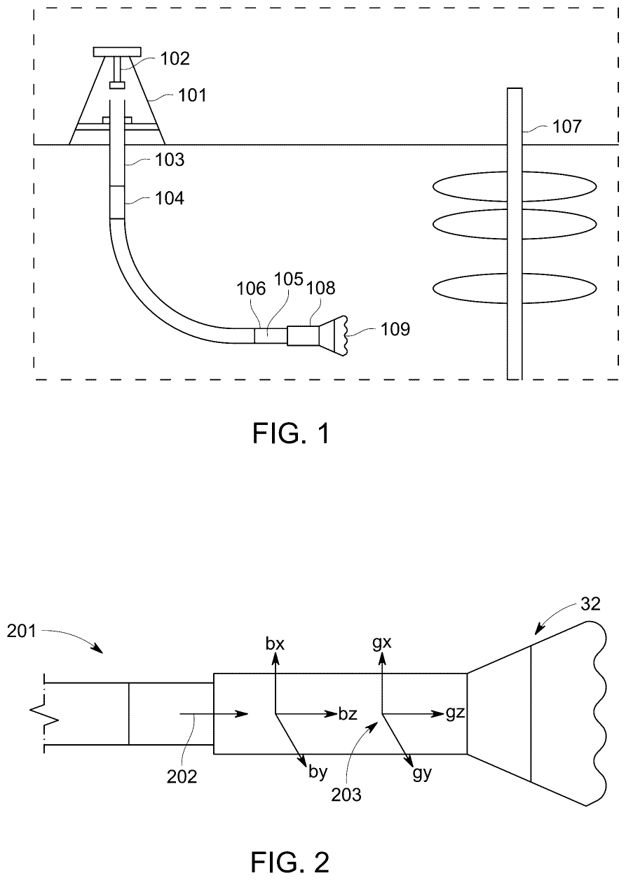

FIG. 1 shows a conventional drilling rig 101 that can be used with the disclosed inventions. In addition to a conventional drilling rig, the disclosed inventions may also be utilized with a coiled tubing drilling rig (not shown). The conventional rig includes the usual derrick 102 and hoisting components for manipulating a drill string 103. Sections of drill pipe 104 are depicted in FIG. 1 as well as an MWD directional tool 105 that can be used to take continuous or static accelerometer and magnetometer measurements during drilling of the well. Additionally, these measurements may be acquired via a wireline sensor assembly (not shown). The drilling configuration can also include a sensor sub 106 containing the MWD components. The drilling configuration can also include a steering assembly 108, which can connect directly or indirectly to the drill bit 109. Also shown in FIG. 1 is a target well 107, which may be a well that the drilling rig is targeting to intersect, or to avoid a collision with. The target well will typically have a magnetic field associated with it that can be excited by various methods known in the art.

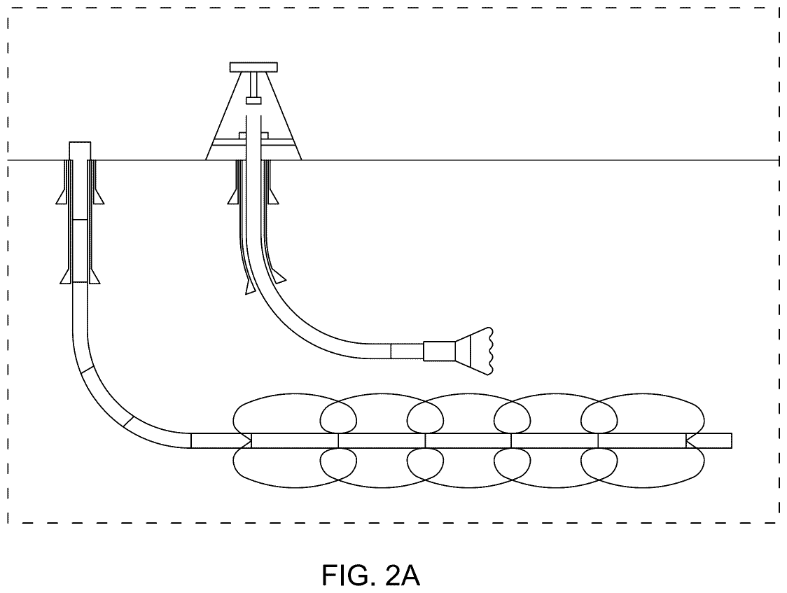

FIG. 2 shows an example MWD tool. The MWD tool 201 may contain a variety of magnetometers, such as, for example, one or more triaxial magnetometer sets 202. The MWD tool may also contain a variety of accelerometers, such as, for example, one or more triaxial accelerometer sets 203. The MWD tool assembly may also contain a sensor for measuring the measured depth of the well. If not part of the MWD, the sensor for measuring depth may be contained elsewhere in the drill string. The MWD tool may also contain one or more processors for processing signals received from any sensors. Processors for processing the signals received from sensors may also be contained elsewhere in the drill string, or alternatively processors for processing signals may also be located on surface. The MWD tool can also transmit signals received from sensors (or other data such as processed signals) to surface by mud pulses and electromagnetic telemetry. Alternatively, wired pipe or part or all of a monoconductor or multiconductor wire may be used to transmit signals (or other data such as processed signals) from the MWD to surface. Magnetic field components measured by the triaxial magnetomer(s) can be designated as bx, by and bz. Similarly, gravitational field components measured by the accelerometer(s) can be designated as gx, gy and gz.

FIG. 2A is similar to FIG. 1 and is another example of a configuration that the inventions claimed herein can be used. FIG. 2A depicts that the magnetic ranging techniques using the pseudo or clean azimuth reading, related calculations and other equipment disclosed herein can be used in a nearly parallel or parallel well configurations.

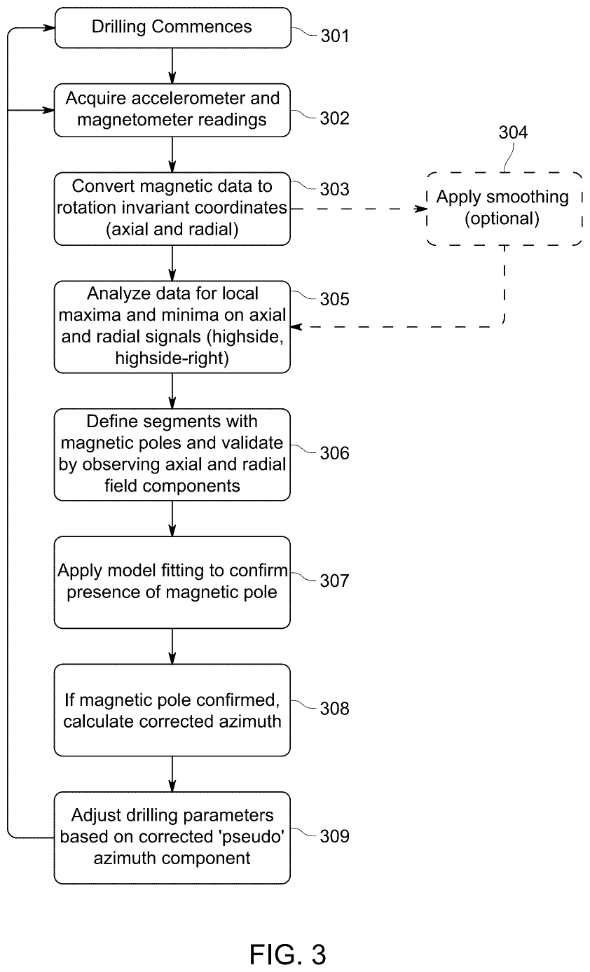

FIG. 3 depicts a flow chart of one disclosed method embodiment. During drilling accelerometer and magnetometer measurements are acquired at 302. The magnetic field components bx, by and bz, gravitational components, gx, gy and gz, as well as measured depth may be gathered by the aforementioned sensors as drilling progresses. The three dimensional magnetic field measured while drilling may be converted at 303 from an x/y/z coordinate system to a rotation invariant high side, right side and axial coordinate system using known methods.

$$Rotation from XYZ Sensor Reference Frame to Borehole Reference Frame$$

$$[ \begin{matrix}{b}_{hs} \\ {b}_{hsr} \\ {b}_{ax}\end{matrix} ] = {R}_{toolface} ( {∅}_{tf} ) [ \begin{matrix}bx \\ by \\ bz\end{matrix} ] \qquad Equation 1$$

Where bx, by, bz are the magnetometer values, Ø_{tf} is the sensor toolface, and bhs, bhsr and bax are the borehole reference frame highside, highside-right and axial components respectively.

The toolface rotation matrix is defined as:

$$Toolface Rotation Matrix$$

$${R}_{toolface} ( {∅}_{tf} ) = [ \begin{matrix}cos ( {∅}_{tf} ) & - sin ( {∅}_{tf} ) & 0 \\ sin ( {∅}_{tf} ) & cos ( {∅}_{tf} ) & 0 \\ 0 & 0 & 1\end{matrix} ] \qquad Equation 2$$

And the toolface angle is calculated as:

$${∅}_{tf} = a tan 2 ( \frac{gy}{- gx} )$$

This computation may be done downhole or at surface.

Optionally, if needed, smoothing methods can now be applied at 304 to the magnetic high side, right side and axial components. This reduces signal noise and enhances the reliability of peak and trough detection. The method proposed, uses gaussian kernel smoothing techniques as an example to the high side, right side and axial components. Other smoothing techniques well known in the art of signal processing, such as moving averages, spline interpolation methods etc. may also be used. Gaussian kernel smoothing is useful for reducing noise in data with uneven or sparse sampling which is a common problem with depth based measurements. It works by averaging nearby values, with closer points having more influence. The smoothing effect is controlled by the bandwidth (tau). A small tau keeps more detail by focusing on nearby points, while a larger tau includes more distant points, creating a smoother result but potentially losing finer details. The values for tau would vary on a case-by-case basis depending on the sampling frequency and resolution of the received data from the MWD.

$$Gaussian kernal function with bandwidh tau :$$

$$G ( x ) = \frac{1}{\sqrt{2 π {τ}^{2}}} {e}^{- \frac{{x}^{2}}{2 {τ}^{2}}} \qquad Equation 3$$

$$Gaussian Kernal Smoothed Signal With data points ( xi , yi )$$

$${y}_{smoothed} ( x ) = \frac{\sum G ( x - {x}_{i} ) \cdot {y}_{i}}{\sum G ( x - {x}_{i} )} \qquad Equation 4$$

Next, the axial magnetic field component is analyzed at 305 to identify local maxima (peaks) and minima (toughs). Thes points indicate changes in the magnetic field's direction, corresponding to the presence of magnetic poles.

The method iterates through detected peaks and troughs at 306 to define segments associated with magnetic poles. The midpoint between each peak and its subsequent trough is calculated to estimate the position of the magnetic pole (s_pole). These segments are validated using criteria like radial amplitude, slope between peak and trough pair for polarity indication, and statistical data to quantify goodness of fit well known in the art of statistics (such as adjusted R-squared) to ensure their significance and rule out potential signal inconstancies that may not be related to magnetic poles. For each identified pole segment, an axial monopole model with a bias term is fitted at 307 to the axial magnetic field data. This model fitting process uses curve fitting techniques to optimize parameters such as magnetic charge (q), radial distance to the pole (d), pole position (s_pole) and bias (b) to best fit the data. Fitting algorithms, such as a non-linear least squares optimization routine can be used to fit the magnetic monopole model to the observed (or smoothed) data points by finding the optimal parameters that minimize the difference between the model's predictions and the observed data.

This method which primarily focuses on the axial component of the magnetic field and monopole equation, eliminates the necessity to have prior knowledge of the earth magnetic field as it is effectively removed by including a bias term in the standard axial field monopole equation. The radial components can be observed here for confirmation that a magnetic pole is present. If so, the radial component (highside or highside-right) will form a peak or trough at the midpoint of the axial peak-trough points (s_pole).

Equations that can be used for the model fitting process are below:

$$Monopole Equation$$

$$\vec{B} = \frac{k * q}{{( s - {s}_{spole} )}^{2} + {d}^{2}} \hat{d} \qquad Equation 5$$

$$Monopole Equation - axial component$$

$${B}_{axial} ( s ) = \frac{k * q}{{( s - {s}_{spole} )}^{2} + {d}^{2}} sin ( θ ) {B}_{axial} ( s ) = \frac{k * q * ( s - {s}_{pole} )}{{[ {( s - {s}_{spole} )}^{2} + {d}^{2} ]}^{3 / 2}} \qquad Equation 6$$

$$With bias term$$

$${B}_{axial} ( s ) = \frac{k * q * ( s - {s}_{pole} )}{{[ {( s - {s}_{spole} )}^{2} + {d}^{2} ]}^{3 / 2}} + {b}_{bias} \qquad Equation 7$$

Next in the method, the “clean” or corrected azimuth is calculated 308 once it is confirmed that a magnetic pole is present (radial component peak or trough occurring between axial peak-trough pair). This can be calculated using the magnetic field components at the axial peak and axial trough of the pole segments where the radial component of the interference is the smallest (corresponding to each of the axial peak and trough) and using the axial component at the solved s_pole pole position (corresponding to the radial peak) where the axial interference is the smallest.

$$Azimuth Calculations ( gx , gy , gz , bx , by ) taken at axial peak and axial trough md locations with bz\_pole extracted from axial value at s\_pole md location .$$

$${azm}_{peak , trough} = \text{} ( arctan ( \frac{gt ( gx * by - gy * bx )}{{bz}_{pole} ( {gx}^{2} + {gy}^{2} ) - gz ( gx * bx + gy * by )} ) ) \qquad Equation 8$$

Where gt (known as g total) is the magnitude of the accelerometer values:

$$gt = \sqrt{{gx}^{2} + {gy}^{2} + {gz}^{2}}$$

Finding the azimuth on both sides of the pole (at axial peak/trough), it can then be averaged to solve the azimuth at the pole position to provide a smoothed and approximate interference-free azimuth reading. (It should be noted, this is the magnetic azimuth which will need to have the appropriate magnetic declination and grid convergence applied specific for the area.)

$$Average peak and trough azimuth calculations for Azimuth Clean at s\_pole md location ( accounting for 360 and 180 crossings )$$

$${azm}_{clean} = a tan 2 ( sin ( azm\_peak ) + sin ( azm\_trough ) , cos ( azm\_peak ) + cos ( azm\_trough ) ) \qquad Equation 9$$

Next in the method at 309, the interference-free azimuth reading is used, along with other data from the magnetometers and accelerometers, to adjust the direction of drilling to achieve the targeted intersection point of a target well, or to steer clear of a well, or other subterranean feature, near the drilling operation. The method may then be repeated in a loop. The method can be carried out using software, hardware, or a combination of both and may use one or more processors and one or more types of computer memory.

By focusing on both axial and radial magnetic components and using smoothing techniques (if necessary), the method significantly improves the accuracy of azimuth calculations near magnetic poles comparable to gyro techniques, thus reducing cost and operational efficiency. The method effectively isolates magnetic interference caused by nearby wells or magnetic anomalies, providing more reliable azimuth data. Accurate azimuth readings obtained using the disclosed methods help maintain accurate well placement, avoid collisions with nearby wells, or assist in intentionally colliding with target wells in some applications, enhancing safety and operational efficiency during drilling (especially when removing the need for gyro). This method is applicable in oil and gas drilling operations, particularly in environments where multiple wells are drilled close to each other, and magnetic interference is a concern. It can be integrated into downhole measurement systems to provide real-time, clean azimuth readings, aiding directional drilling decisions and assist in passive magnetic ranging applications. The method is also applicable in other subterranean drilling operations where it is desirous for drilling operations to intersect or avoid other subterranean magnetic anomalies.

While the inventions herein have been illustrated and described in detail in the drawings and foregoing description, the same is to be considered as illustrative and not restrictive in character, it being understood that only the preferred embodiments have been shown and described and that all changes and modifications that come within the spirit of the invention are desired to be protected.

What is claimed is:

1. A method for magnetic ranging comprising:
acquiring magnetic field readings from a sensor;
acquiring accelerometer readings from a sensor;
converting the magnetic field readings from an x, y z coordinate system to a rotation invariant magnetic high side, high side right and axial coordinate system;
analyzing the axial magnetic field component to identify local peaks and troughs;
identifying magnetic poles based on each identified peak and trough;
analyzing the high side or high side right component to confirm the presence of a magnetic pole;
calculating a clean azimuth reading; and
adjusting a direction of drilling using at least the clean azimuth reading.

2. The method of claim 1 further comprising applying a smoothing technique to the magnetic high side, high side right and axial components.

3. The method of claim 2 wherein the smoothing technique is gaussian kernel smoothing.

4. The method of claim 2 wherein the smoothing technique is spline interpolation smoothing.

5. The method of claim 2 wherein the smoothing technique is moving average smoothing.

6. The method of claim 1 further comprising applying a fitting algorithm to fit the axial magnetic field data to an axial monopole model to eliminate signal inconsistencies unrelated to magnetic poles.

7. A system for magnetic ranging comprising:
at least one magnetometer capable of acquiring magnetic field readings;
at least one accelerometer capable of acquiring gravitational readings;
one or more processors that (i) converts the magnetic field readings from an x, y z coordinate system to a rotation invariant magnetic high side, high side right and axial coordinate system, (ii) analyzes the axial magnetic field component to identify local peaks and troughs, (iii) identifies magnetic poles based on each identified peak and tough, (iv) analyzes a radial component of the magnetic filed to confirm the presence of a magnetic pole, (v) calculates a clean azimuth reading; and
a steering assembly that adjusts a direction of drilling using at least the clean azimuth reading.

8. The system of claim 7 wherein the one of more processors applies a smoothing technique to the magnetic high side, high side right and axial components.

9. The system of claim 8 wherein the smoothing technique is gaussian kernel smoothing.

10. The system of claim 7 wherein the radial component of the magnetic field that is analyzed by the one or more processors to confirm the presence of a magnetic pole is the high side component.

11. The system of claim 7 wherein the radial component of the magnetic field that is analyzed by the one or more processors to confirm the presence of a magnetic pole is the high side right component.

12. The system of claim 7 wherein the one or more processors applies a fitting algorithm to fit the axial magnetic field data to an axial monopole model to eliminate signal inconsistencies unrelated to magnetic poles.
